(19) United States
(12) Patent Application Publication
(10) Pub. No.: US 2024/0194763 A1
(43) Pub. Date: Jun. 13, 2024

(54) HEMT TRANSISTOR

(71) Applicant: STMicroelectronics International N.V., Geneva (CH)

(72) Inventors: Aurore CONSTANT, Tours (FR); Ferdinando IUCOLANO, Gravina di Catania (IT); Cristina TRINGALI, Augusta (IT)

(21) Appl. No.: 18/523,185

(22) Filed: Nov. 29, 2023

(30) Foreign Application Priority Data
Dec. 13, 2022 (FR) 2213256

(51) Int. Cl. H01L 29/66; H01L 29/20; H01L 29/205; H01L 29/778

(52) U.S. Cl. CPC H01L 29/66462; H01L 29/2003; H01L 29/205; H01L 29/7786

(57) ABSTRACT

The present disclosure relates to a HEMT transistor comprising a first semiconductor layer, a gate arranged on a first surface of the first semiconductor layer, a first passivation layer made of a first material on the sides of the gate, the first passivation layer further extending over a first portion of said surface of the first semiconductor layer, and a second passivation layer made of a second material different from the first material on a second portion of said surface of the first semiconductor layer next to the first passivation layer.

### CROSS REFERENCE TO RELATED APPLICATION

This application is a translation of and claims the priority benefit of French Patent Application Number 22/13256, filed on Dec. 13, 2022, entitled “Transistor HEMT,” which is hereby incorporate by reference to the maximum extent allowable by law.

### TECHNICAL FIELD

The present disclosure generally concerns the field of transistors and more particularly the field of high electron mobility transistors also called HEMT.

### BACKGROUND

HEMT transistors rely on a heterojunction having a two-dimensional electron gas also called 2DEG forming at their surface.

There exists a need to improve HEMT transistors and their manufacturing methods.

### BRIEF SUMMARY

To achieve this, an embodiment provides a HEMT transistor comprising:
a first semiconductor layer;
a gate arranged on a first surface of the first semiconductor layer;
a first passivation layer made of a first material on the sides of the gate, the first passivation layer further extending over a first portion of said surface of the first semiconductor layer; and
a second passivation layer made of a second material different from the first material on a second portion of said surface of the first semiconductor layer next to the first passivation layer.

According to an embodiment, the first semiconductor layer is based on gallium nitride.

According to an embodiment, the first semiconductor layer is made of aluminum-gallium nitride.

According to an embodiment, the first passivation layer is made of alumina.

According to an embodiment, the second passivation layer is made of aluminum nitride.

According to an embodiment, the HEMT transistor comprises a second semiconductor layer in contact with a second surface of the first semiconductor layer, opposite to the first surface.

According to an embodiment, the second semiconductor layer is made of gallium nitride.

According to an embodiment, the HEMT transistor comprises a source contact metallization and a drain contact metallization, respectively arranged on either side of the gate.

According to an embodiment, the passivation layer extends laterally from the gate towards the drain contact metallization, over a portion only of the surface between the gate and the drain contact metallization.

According to an embodiment, the passivation layer extends laterally from the gate to the source contact metallization.

According to an embodiment, the second passivation layer extends laterally from an edge of the first passivation layer located between the gate and the drain contact metallization, to the drain contact metallization.

According to an embodiment, the first passivation layer is covered with an insulating layer.

According to an embodiment, the second passivation layer covers the side of the insulating layer located between the gate and the drain contact metallization and extends over a portion of the insulating layer towards the gate.

Another embodiment provides a method of forming an HEMT transistor, comprising the following successive steps:
a) forming a first semiconductor layer;
b) forming a gate on a first surface of the first semiconductor layer;
c) forming a first passivation layer made of a first material on the sides of the gate, the first passivation layer further extending over a first portion of said surface of the first semiconductor layer; and
d) forming a second passivation layer made of a second material different from the first material on a second portion of said surface of the first semiconductor layer next to the first passivation layer.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a partial simplified cross-section view of an example of an HEMT transistor according to an embodiment;

FIG. 2A, FIG. 2B, FIG. 2C, FIG. 2D, FIG. 2E, FIG. 2F, FIG. 2G, and FIG. 2I are cross-section views illustrating steps of an example of a method of manufacturing the HEMT transistor illustrated in FIG. 1.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the applications that the described HEMT transistors may have are not detailed, the embodiments being compatible with usual applications of HEMT transistors. The field of HEMT transistors, capable of withstanding relatively high voltages in the off state, for example, voltages in the order of from 100 to 650 volts, is more particularly considered herein.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

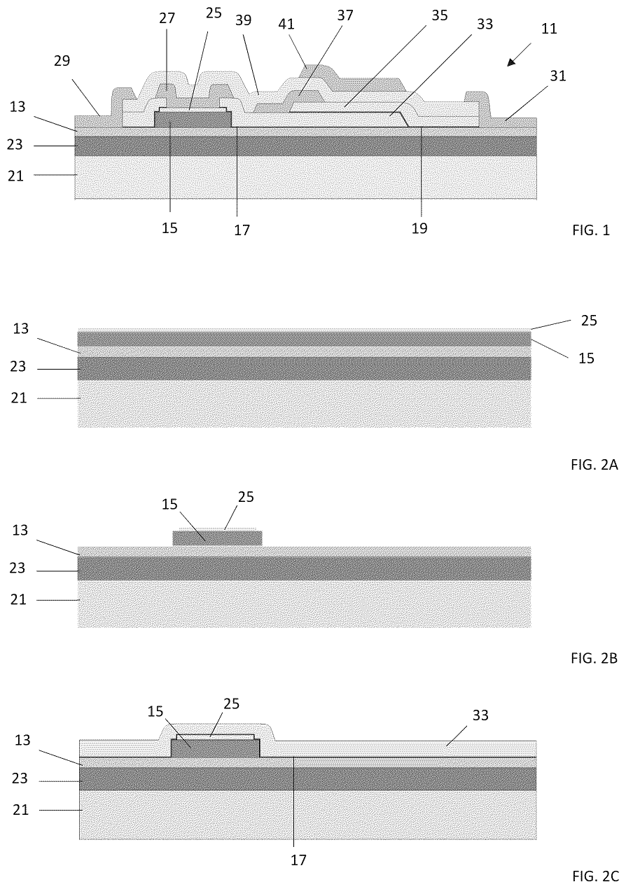

FIG. 1 is a partial simplified cross-section view of an example of an HEMT transistor 11 according to an embodiment.

HEMT transistor 11 comprises a first semiconductor layer 13, arranged on a second conductive layer 23. Semiconductor layer 13 is for example in contact, by its lower surface, with the upper surface of conductive layer 23. As an example, the stack comprising semiconductor layer 13 and semiconductor layer 23 rests on a substrate 21. Semiconductor layer 23 is for example in contact, by its lower surface, with the upper surface of substrate 21. The interface between first semiconductor layer 13 and second semiconductor layer 23 defines a heterojunction at the surface of which a two-dimensional electron gas 2DEG also called electron channel is formed.

Semiconductor layers 13 and 23 are for example made of semiconductor materials of III-V type, for example, based on gallium nitride (GaN). Semiconductor layer 13 is for example made of aluminum-gallium nitride (AlGaN). Semiconductor layer 23 is for example made of gallium nitride.

As an example, substrate 21 is made of a semiconductor material. Substrate 21 is for example made of silicon, or of silicon carbide. As a variant, substrate 21 is made of aluminum nitride. Substrate 21 for example comprises, on its upper surface side, a buffer layer, not detailed in the drawings, for example, made of gallium nitride. The buffer layer is for example in contact, by its upper surface, with the lower surface of semiconductor layer 23.

HEMT transistor 11 comprises a gate 15 on the upper surface of semiconductor layer 13. Gate 15 is for example in contact, by its lower surface, with the upper surface of semiconductor layer 13.

Gate 15 is for example made of a semiconductor material, for example, of a III-V-type semiconductor material, for example made of gallium nitride, for example P-type doped.

As an example, HEMT transistor 11 further comprises a source contact metallization 29 and a drain contact metallization 31. As an example, contact metallizations 29 and 31 are based on titanium, titanium nitride, and/or on an alloy of aluminum and of copper. Source and drain contact metallizations 29 and 31 for example each define an ohmic contact with semiconductor layer 13. Contact metallizations 29 and 31 are for example located on top of and in contact with semiconductor layer 13, on either side of gate 15.

HEMT transistor 11 further comprises a first passivation layer 17 made of a first material covering the sides of gate 15 and further extending over a portion of the upper surface of first semiconductor layer 13. As an example, passivation layer 17 is in contact, by its lower surface, with the upper surface of semiconductor layer 13. In the embodiment of FIG. 1, passivation layer 17 covers a portion only of the upper surface of semiconductor layer 13, located next to gate 15, for example, at the periphery of gate 15. More particularly, in this example, passivation layer 17 extends laterally from gate 15 towards drain contact metallization 31, over a portion only of the surface between gate 15 and drain contact metallization 31. In other words, passivation layer 17 does not extend all the way to drain contact metallization 17. In this example, passivation layer 17 further extends laterally from gate 15 to source contact metallization 29.

As an example, passivation layer 17 further covers a peripheral portion of the upper surface of gate 15.

HEMT transistor 11 further comprises a second passivation layer 19 made of a second material different from the material of layer 17. Second passivation layer 19 is arranged on another portion of the upper surface of semiconductor layer 13. As an example, passivation layer 19 is in contact with the upper surface of first semiconductor layer 13. More precisely, passivation layer 19 is formed next to passivation layer 17 and covers a portion of semiconductor layer 13 which is not covered with passivation layer 17. Passivation layers 17 and 19 are for example in contact by their sides. In the shown example, passivation layer 19 extends laterally from the edge of passivation layer 17 located between gate 15 and drain contact metallization 31, all the way to drain contact metallization 31.

Passivation layers 17 and 19 for example each have a thickness in the range from 2 nm to 20 nm, for example in the range from 5 nm to 10 nm. Passivation layers 17 and 19 for example substantially have the same thickness.

Passivation layer 17 is for example made of a dielectric material, for example, of alumina (Al₂O₃) or of difluorooxonium (HfO₂). Passivation layer 19 is for example made of another dielectric material, for example, of aluminum nitride (AlN) or of silicon nitride (SiN).

As an example, gate 15 is topped with a layer 25, optional, made of a metallic material, for example, based on titanium nitride. Layer 25 is for example in contact with gate 15. Metal layer 25 for example covers the entire surface of the upper surface of gate 15. As a variant, metal layer 25 extends over a central portion only of the upper surface of gate 15, so that a peripheral portion of the upper surface of gate 15 is not covered with metal layer 25. Passivation layer 17 for example extends laterally all the way to metal layer 25.

Layer 25 is for example topped with a gate contact metallization 27 and is for example in contact therewith. As an example, gate contact metallization 27 is based on titanium nitride and/or on an alloy of aluminum and copper.

HEMT transistor 11 for example comprises a plurality of levels of insulating layers having metallizations formed inside and on top of them.

As an example, HEMT transistor 11 comprises a first insulating layer 33 on top of and in contact with the upper surface of passivation layer 17. As an example, insulating layer 33 covers the entire surface of passivation layer 17, and does not cover passivation layer 19. Insulating layer 33 is for example opened in front of a central portion of gate 15 to be crossed by gate contact metallization 27. Insulating layer 33 is for example made of a dielectric material, for example, of an oxide, for example, of silicon dioxide (SiO₂).

As an example, passivation layer 19 covers the side of insulating layer 33 located between gate 15 and drain contact metallization 31, and further extends over a portion of insulating layer 33 towards gate 15. Thus, starting from drain contact metallization 31, passivation layer 19 covers the portion of the upper surface of semiconductor layer 13 between drain contact metallization 31 and passivation layer 17, then further extends over insulating layer 33, so that a portion of passivation layer 19 is located in front of passivation layer 17 and separated therefrom by insulating layer 33.

As an example, HEMT transistor 11 comprises a second insulating layer 35 on top of and in contact with the upper surface of passivation layer 19. As an example, insulating layer 35 has a side in contact with drain contact metallization 31 and extends towards source contact metallization 29. As an example, insulating layer 35 covers, for example exclusively, the entire surface of passivation layer 19. Insulating layer 35 thus for example extends over the portion of the upper surface of semiconductor layer 13 which is not covered by insulating layer 33 and over the peripheral portion of insulating layer 33. Insulating layer 35 is for example made of a dielectric material, for example, of silicon nitride (SiN) or of an oxide, for example of silicon dioxide (SiO₂).

As an example, HEMT transistor 11 comprises a region 37 simultaneously extending over a portion of the surface of first insulating layer 33 and over a portion of the surface of second insulating layer 35. Metal region 37 is thus arranged on two different insulating layer levels. As an example, metal region 37 is based on titanium nitride and/or on an alloy of aluminum and of copper. Metal region 37 is for example made of the same material as gate contact metallization 27.

HEMT transistor 11 may comprise a third insulating layer 39 covering the entire structure except for source and drain contact metallizations 29 and 31. Third insulating layer 39 is for example made of the same material as insulating layers 33 and 35. The HEMT transistor 11 illustrated in FIG. 1 comprises a metal region 41 formed on insulating layer 39. As an example, metal region 41 is made of the same material as metal region 37.

Metal region 37 and 41 for example have the function of changing the profile of the electric field distribution of the drain-side edge of the gate (the right edge of the gate in FIG. 1), and reducing the peak of the critical electric field, thereby increasing the avalanche voltage. For example, the metal regions 37 and 41 are called field plates.

In the transistor of FIG. 1, the 2DEG channel is for example normally off, that is, it is interrupted under gate 15, which prevents the flowing of a current between the source and the drain of the transistor. The transistor is then said to be in the off state. The channel may be restored (that is, made conductive) by the biasing of gate 15. In this case, a current may flow between the source and the drain of the transistor. The transistor is then said to be in the on or conductive state. The described embodiments may also apply to normally-on transistors.

The presence of passivation layers 17 and 19 allows the protection of the upper surface of semiconductor layer 13 on which dangling bonds may be present and likely to generate leakage currents and/or a decrease in the breakdown voltage of the transistor. Passivation layers 17 and 19 fill these bonds to make the surface of semiconductor layer 13 electrically inactive.

Passivation layers 17 and 19 also enable to protect semiconductor layer 13 against oxidation and to improve its state condition to which the 2DEG channel is sensitive.

In the embodiment of FIG. 1, the provision of two passivation layers 17 and 19 of distinct natures between the gate and the drain of the transistor advantageously enables to improve the tradeoff between the on-state resistance of the transistor and off-state leakage currents.

First passivation layer 17, and more particularly the portion of passivation layer 17 located on the sides of gate 15, enables to increase the resistivity of the 2DEG channel under and around the gate, which generates a decrease in the electric field formed at the corner of gate 15, and thus a decrease in leakage currents.

Second passivation layer 19 enables to introduce positive charges at the interface between the passivation layer and first semiconductor layer 13, which locally increases the electronic density in the 2DEG channel, and thus locally decreases the resistivity of the 2DEG channel.

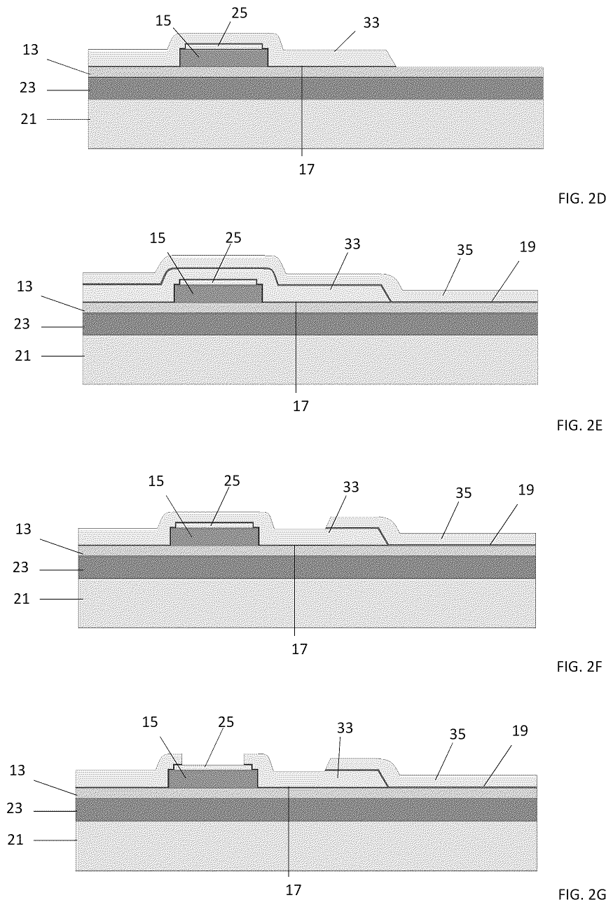

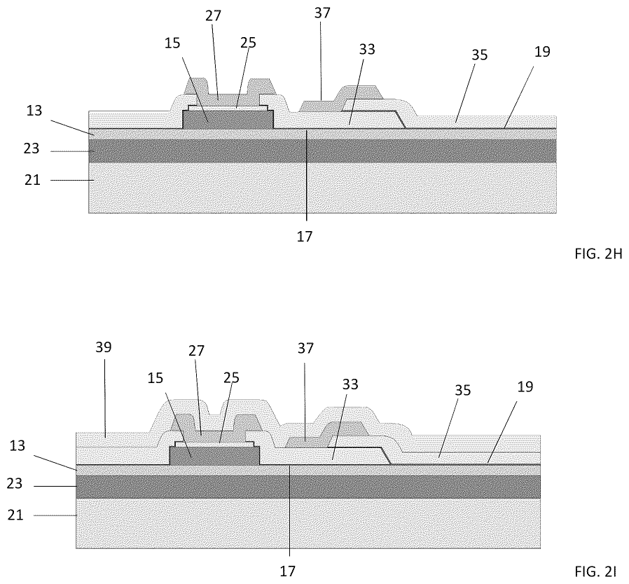

FIG. 2A, FIG. 2B, FIG. 2C, FIG. 2D, FIG. 2E, FIG. 2F, FIG. 2G, and FIG. 2I are cross-section views illustrating successive steps of an example of a method of manufacturing the HEMT transistor illustrated in FIG. 1.

FIG. 2A illustrates an initial structure comprising, in the order, from the lower surface of the structure, substrate 21, second semiconductor layer, and first semiconductor layer 13. The initial structure further comprises a gate layer 15 topped with metal layer 25. In the initial structure illustrated in FIG. 2A, layers 23, 13, 15, and 25 extend continuously and with a substantially uniform thickness over the entire upper surface of substrate 21.

FIG. 2B illustrates a structure obtained at the end of a step of local etching of gate layer 15 and of metal layer 25 to only keep a portion of each layer forming the gate stack of the transistor of FIG. 1.

During this step, metal layer 25 is etched for example by a plasma etching method, for example, by a chlorine-based plasma etching method, for example by a boron trichloride (BCl₃) plasma etching method.

During this step, gate 15 is further etched for example by a plasma etching method, for example by a chlorine-based plasma etching method, for example, by a boron trichloride (BCl₃) and oxygen (O₂) plasma etching.

As an example, gate 15 and layer 25 are etched through a same mask. At the end of this step, gate 15 and layer 25 are thus aligned, that is, their sides are aligned.

The step of etching of gate 15 and of layer 25 are for example carried out simultaneously, that is, they are carried out within a same etch chamber. As a variant, the steps of etching of gate 15 and of layer 25 are successively carried out one after the other.

Layer 25 may for example undergo another etching, for example, a wet etching, to remove therefrom a peripheral portion and thus expose a peripheral portion of the upper surface of gate 15. This etching is for example performed through a hard mask, for example, made of silicon nitride.

These etch steps are for example followed by a step of cleaning of the upper surface of the structure to remove for example residues originating from the etch mask (s) and impurities resulting from the etching of layer 25 and of gate 15. The cleaning of the structure for example comprises a step of stripping by oxygen and nitrogen (N₂) plasma. The cleaning of the structure may further comprise a step of removal of organic residues by means of a solvent.

FIG. 2C illustrates a structure obtained at the end of a step of forming of passivation layer 17 and of insulating layer 33 on the upper surface of the structure illustrated in FIG. 2B.

During this step, passivation layer 17 is first manufactured in continuous fashion, so that it covers the entire upper surface of the structure illustrated in FIG. 2B.

Passivation layer 17 for example formed in contact with the upper surface of semiconductor layer 13, the sides of gate 15, and the sides and the upper surface of layer 25.

Passivation layer 17 is for example formed by a thin layer deposition method, for example, an atomic layer deposition or ALD method. As an example, the method of deposition of passivation layer 17 is plasma-enhanced. At the end of this step, passivation layer 17 has a thickness for example in the range from 1 nm to 10 nm, for example in the range from 1.5 nm to 5 nm, for example in the order of 2.5 nm.

Then, insulating layer 33 is, in this example, formed in continuous fashion, so that it covers the entire upper surface of passivation layer 17. Insulating layer 33 is for example formed in contact with passivation layer 17. Insulating layer 33 is for example formed by a plasma-enhanced chemical vapor deposition or PECVD. At the end of this step, insulating layer 33 has a thickness for example in the range from 150 nm to 400 nm, for example in the range from 200 nm to 350 nm, for example, in the order of 300 nm.

As an example, the steps of deposition of passivation layer 17 and of insulating layer 33 are preceded by one or a plurality of steps of preparation of the surface of the structure illustrated in FIG. 2B. The preparation of the surface of the structure illustrated in FIG. 2B may comprise a cleaning for example consisting of a chemical cleaning by means of acid, for example, hydrogen chloride (HCl) or hydrogen fluoride (HF). The preparation of the surface of the structure illustrated in FIG. 2B may further comprise a cleaning for example consisting of a surface oxidation. Passivation layer 17 will thus be formed in contact with an oxide film, itself formed in contact with the upper surface of layer 13.

FIG. 2D illustrates a structure obtained at the end of a step of etching of passivation layer 19 and of insulating layer 33.

More particularly, during this step, passivation layer 17 and insulating layer 33 are removed in front of a portion of semiconductor layer 13. As an example, layers 17 and 33 are kept next to gate 15, and removed outside of the periphery of gate 15, here in a portion located to the right of gate 15.

As an example, the removal of layers 17 and 33 is performed by plasma etching, for example, based on fluorine, for example, based on carbon tetrafluoride (CF₄).

The etching of layers 17 and 33 is for example selective and does not etch gallium nitride semiconductor layer 13. The etching of layers 17 and 33 then stops with the exposing of the upper surface of layer 13.

These etch steps are for example followed by a step of cleaning of the upper surface of the structure for example similarly to what has been described in relation with FIG. 2B.

FIG. 2E illustrates a structure obtained at the end of a step of forming of passivation layer 19 and of insulating layer 35 on the upper surface of the structure illustrated in FIG. 2D.

During this step, passivation layer 19 is first formed in continuous fashion, so that it covers the entire upper surface of the structure illustrated in FIG. 2D.

Passivation layer 19 is for example formed in contact with the upper surface of insulating layer 33 and the portion of semiconductor layer 13 which is not covered with passivation layer 17. As an example, passivation layer 19 further covers the etched side of layers 17 and 33.

Passivation layer 19 is for example formed by a thin layer deposition method, for example, an atomic layer deposition or ALD method. As an example, the method of deposition of passivation layer 19 is plasma-enhanced. At the end of this step, passivation layer 19 has a thickness for example in the range from 1 nm to 10 nm, for example in the range from 2 nm to 8 nm, for example in the order of 5 nm.

Then, insulating layer 35 is, in this example, formed in continuous fashion, so that it covers the entire upper surface of passivation layer 19. Insulating layer 35 is for example formed in contact with passivation layer 19. Insulating layer 35 is for example formed by a method identical to the method of forming of layer 33 described in relation with FIG. 2C. At the end of this step, insulating layer 35 has a thickness for example in the range from 150 nm to 400 nm, for example in the range from 200 nm to 350 nm, for example, in the order of 300 nm.

As an example, the steps of deposition of passivation layer 19 and of insulating layer 35 are preceded by one or a plurality of steps of preparation of the surface of the structure illustrated in FIG. 2D similarly to what has been described in relation with FIG. 2C.

FIG. 2F illustrates a structure obtained at the end of a step of etching of the layers 19 and 35 of the structure illustrated in FIG. 2E.

More particularly, during this step, passivation layer 19 and insulating layer 35 are removed in front of gate 15 and in front of a peripheral portion of gate 15. In other words, during this step, a portion of layers 19 and 33 is removed so that, at the end of this step, passivation 19 and insulating layer 35 cover the portion of semiconductor layer 13 which is not covered with passivation layer 17, the side of insulating layer 33, here located on the right-hand side of gate 15, and so that they further extend over a portion of insulating layer 33 towards gate 15, without reaching gate 15.

As an example, the removal of layers 19 and 35 is performed by a method similar to the etching method of layers 17 and 33 described in relation with FIG. 2D.

The removal of layers 19 and 33 is for example followed by a step of cleaning of the upper surface of the structure, for example, similarly to what has been described in relation with FIG. 2B.

FIG. 2G illustrates a structure obtained at the end of a step of opening of layers 17 and 33 in front of the gate 15 of the structure illustrated in FIG. 2F.

More particularly, during this step, passivation layer 17 and insulating layer 33 are removed in front of a central portion of the upper surface of gate 15.

As an example, the removal of layers 17 and 33 is performed by plasma etching, for example, based on fluorine, for example, based on carbon tetrafluoride (CF₄).

The etching of layers 17 and 33 is for example non-selective over layer 25, the etching then stops with the exposing of the upper surface of layer 25. The partial removal of layers 17 and 33 is for example followed by a step of cleaning of the upper surface of the structure, for example similarly to what has been described in relation with FIG. 2B.

FIG. 2H illustrates a structure obtained at the end of a step of forming of gate contact metallization 27 and region 37 on the upper surface of the structure illustrated in FIG. 2G.

During this step, gate contact metallization 27 is formed in the opening formed in layers 17 and 33 in front of the central portion of gate 15. As an example, gate contact metallization 27 is formed on top of and in contact with layer 25. As an example, during this step, region 37 is simultaneously formed on a portion of the surface of first insulating layer 33 and on a portion of the surface of second insulating layer 35. Gate contact metallization 27 and region 37 are for example formed by deposition of one or a plurality of layers made of a metallic material followed by an etch step.

As an example, the step of forming of gate contact metallization 27 and of region 37 is preceded by a step of preparation of the surface of the structure illustrated in FIG. 2G, for example consisting of a chemical cleaning by means of acid, for example, hydrogen chloride (HCl).

FIG. 2I illustrates a structure obtained at the end of a step of forming of insulating layer 39 on the upper surface of the structure illustrated in FIG. 2H.

During this step, insulating layer 39 is for example formed in continuous fashion, so that it covers the entire upper surface of the structure illustrated in FIG. 2H, that is, the upper surface and the sides of gate contact metallization 27 and of region 37, a portion of layer 33, and a portion of layer 35. Insulating layer 39 is for example formed by a method identical to the method of forming layer 33 described in relation with FIG. 2C. At the end of this step, insulating layer 39 has a thickness for example in the range from 150 nm to 400 nm, for example in the range from 200 nm to 350 nm, for example, in the order of 300 nm.

At the end of this step, the ohmic contacts and more particularly source and drain contact metallizations 29 and 31 are for example formed to form the structure illustrated in FIG. 1.

For this purpose, openings intended to receive source and drain contact metallizations 29 and 31 are, first, created in layers 33 and 35. The openings are for example formed by a plasma etching method, for example, based on fluorine, for example, based on carbon tetrafluoride (CF₄). The above-mentioned etching is for example selective and does not etch gallium nitride semiconductor layer 13. The etching of layers 33 and 35 thus stops when the upper surface of layer 13 is exposed. The step of forming of the openings intended to receive contact metallizations 29 and 31 is for example followed by a step of cleaning of the upper surface of the structure, for example, similarly to what has been described in relation with FIG. 2B.

As an example, a step of preparation of the surface of the upper side of layer 13 in the openings may be provided. This step for example comprises a chemical cleaning by means of acid, for example hydrogen chloride (HCl).

Then, source and drain contact metallizations 29 and 31 are for example formed in the previously-formed openings and region 41 is for example formed on the upper surface of layer 39. Metallizations 29, 31 and region 41 are for example formed by deposition of one or a plurality of layers of a metallic material followed by an etch step.

Various embodiments and variants have been described. Those skilled in the art will understand that certain features of these various embodiments and variants may be combined, and other variants will occur to those skilled in the art.

In particular, it may be provided for the ohmic contact metallizations, for example, the source and drain contact metallizations, to be formed before the forming of the gate contact metallization.

Further, although the embodiments and implementation modes have been described with an aluminum nitride passivation layer 19, they are not limited to this specific example, and passivation layer 19 may be made of another dielectric material carrying positive charges.

Further, although an example of embodiment where the transistor gate 15 is in contact with the upper surface of upper semiconductor layer 13 has been described hereabove, as a variant, gate 15 may be separated from semiconductor layer 13 by a gate insulator layer.

Finally, the embodiments are not limited to the examples of numerical values nor to the examples of materials mentioned in the present disclosure.

Finally, the practical implementation of the described embodiments and variations is within the abilities of those skilled in the art based on the functional indications given hereabove.

1. A HEMT transistor comprising:
a first semiconductor layer;
a gate arranged on a first surface of the first semiconductor layer;
a first passivation layer made of a first material on two or more sides of the gate, the first passivation layer further extending over a first portion of said first surface of the first semiconductor layer; and
a second passivation layer made of a second material different from the first material on a second portion of said first surface of the first semiconductor layer next to the first passivation layer.

2. The HEMT transistor according to claim 1, wherein the first semiconductor layer is based on gallium nitride.

3. The HEMT transistor according to claim 2, wherein the first semiconductor layer is made of aluminum-gallium nitride.

4. The HEMT transistor according to claim 1, wherein the first passivation layer is made of alumina.

5. The HEMT transistor according to claim 1, wherein the second passivation layer is made of aluminum nitride.

6. The HEMT transistor according to claim 1, comprising a second semiconductor layer in contact with a second surface of the first semiconductor layer, opposite to the first surface.

7. The HEMT transistor according to claim 6, wherein the second semiconductor layer is made of gallium nitride.

8. The HEMT transistor according to claim 1, comprising a source contact metallization and a drain contact metallization, respectively arranged on either side of the gate.

9. The HEMT transistor according to claim 8, wherein the first passivation layer extends laterally from the gate towards the drain contact metallization, over a portion only of the first surface between the gate and the drain contact metallization.

10. The HEMT transistor according to claim 8, wherein the first passivation layer extends laterally from the gate to the source contact metallization.

11. The HEMT transistor according to claim 8, wherein the second passivation layer extends laterally from an edge of the first passivation layer located between the gate and the drain contact metallization, to the drain contact metallization.

12. The HEMT transistor according to claim 1, wherein the first passivation layer is covered with an insulating layer.

13. The HEMT transistor according to claim 12, wherein the second passivation layer covers the side of the insulating layer located between the gate and a drain contact metallization and extends over a portion of the insulating layer towards the gate.

14. Method of forming an HEMT transistor comprising the following successive steps:
a) forming a first semiconductor layer;
b) forming a gate on a first surface of the first semiconductor layer;
c) forming a first passivation layer made of a first material on two or more sides of the gate, the first passivation layer further extending over a first portion of said first surface of the first semiconductor layer; and
d) forming a second passivation layer made of a second material different from the first material on a second portion of said first surface of the first semiconductor layer next to the first passivation layer.
